(19) United States
(12) Patent Application Publication
(10) Pub. No.: US 2018/0019689 A1
(43) Pub. Date: Jan. 18, 2018

(54) VIBRATION ACTUATOR HAVING A STABLE ROTATIONAL DRIVING PERFORMANCE, AND ELECTRONIC APPARATUS

(71) Applicant: CANON KABUSHIKI KAISHA, Tokyo (JP)

(72) Inventor: Hiroyuki Seki, Oyama-shi (JP)

(21) Appl. No.: 15/543,071

(22) PCT Filed: Mar. 18, 2016
(86) PCT No.: PCT/JP2016/059784

§ 371 Date: Jul. 12, 2017

(30) Foreign Application Priority Data
Mar. 25, 2015 (JP) 2015-062380

(51) Int. Cl. H02N 2/10; H02N 2/12; H02N 2/00; H01L 41/083

(52) U.S. Cl. CPC H02N 2/106; H02N 2/0015; H02N 2/103; H02N 2/123; H02N 2/0045; H01L 41/0835; H02N 2/0065

(57) ABSTRACT

A vibration actuator difficult to be affected by an external force. A vibration element is held by a shaft. A driven element is held in pressure contact with an elastic body, and a bearing member is joined to the driven element in a manner rotatable about the shaft as a rotational axis. Vibrations excited in the vibration element cause the vibration element and the driven element to rotate relative to each other about the shaft. In the driven element, a connecting portion connects between a main body and a gear provided outside the main body. The degree of freedom of the main body with respect to the bearing member is restricted in other directions than a direction of rotation thereof and a thrust direction of the shaft. The connecting portion has a lower flexural rigidity in a direction parallel to the rotational axis than the main body and the gear.

### TECHNICAL FIELD

The invention relates to a vibration actuator having a stable rotational driving performance, in which a vibration element and a driven element are brought into pressure contact with each other, and vibrations are excited in the vibration element, to thereby move the driven element relative to the vibration element, and an electronic apparatus including the vibration actuator, and more particularly to the construction of the driven element as well as the support mechanism and pressurizing mechanism of the vibration actuator.

### BACKGROUND ART

As the vibration actuator in which the vibration element and the driven element are brought into pressure contact with each other, and vibrations are excited in the vibration element, to thereby move the driven element relative to the vibration element, there has been known one configured to cause the vibration element and the driven element to rotate relative to each other. As an example of this type of vibration actuator, PTL 1 describes an ultrasonic motor configured to excite vibrations in a vibration element, and drive a moving body in contact with the vibration element and an output take-out gear, for rotation about the axis, to thereby take out rotational output.

### CITATION LIST

### Patent Literature

PTL1: Japanese Patent Laid-Open Publication No. H11-237053

In order to efficiently take out the rotational output from the vibration actuator described in PTL 1, it is necessary to join the moving body and the output take-out gear to each other or frictionally hold them with a large pressurizing force, such that they are prevented from sliding relative to each other. In this case, when the output take-out gear and external output transmission means in mesh with the output take-out gear are disposed in a state in which respective rotational axes thereof are inclined relative to each other, the output take-out gear receives from the external output transmission means not only rotational reaction force but also a force (rotation moment) that causes the output take-out gear to be inclined. In this case, the moving body is inclined relative to the vibration element, which causes reduction of output power.

### SUMMARY OF INVENTION

### Technical Problem

The invention provides a vibration actuator difficult to be affected by an external force and having a stable rotational driving performance.

### Solution to Problem

Accordingly, in a first aspect of the invention, there is provided a vibration actuator, comprising a vibration element having an elastic body and an electromechanical energy conversion element joined to the elastic body, a shaft member configured to hold the vibration element, a driven element in pressure contact with the elastic body, and a bearing member joined to the driven element and rotatable with respect to the shaft member, wherein vibrations excited in the vibration element by application of a predetermined AC voltage to the electromechanical energy conversion element cause the vibration element and the driven element to rotate relative to each other about the shaft member as a rotational axis, wherein the driven element includes a main body configured to be frictionally driven by the vibration element, an outer peripheral portion, and a connecting portion connecting between the main body and the outer peripheral portion, and wherein the main body has a degree of freedom thereof with respect to the bearing member restricted in other directions than a direction of rotation thereof and a thrust direction of the shaft member, and flexural rigidity of the connecting portion in a direction parallel to the rotational axis is lower than flexural rigidity of the main body and the outer peripheral portion.

Accordingly, in a second aspect of the invention, there is provided an electronic apparatus including a vibration actuator configured to output a rotational driving force, and a member configured to be moved by a rotational driving force output from the vibration actuator to a predetermined position to be positioned thereat, wherein the vibration actuator comprises a vibration element having an elastic body and an electromechanical energy conversion element joined to the elastic body, a shaft member configured to hold the vibration element, a driven element in pressure contact with the elastic body, and a bearing member joined to the driven element and rotatable with respect to the shaft member, wherein vibrations excited in the vibration element by application of a predetermined AC voltage to the electromechanical energy conversion element cause the vibration element and the driven element to rotate relative to each other about the shaft member as a rotational axis, wherein the driven element includes a main body configured to be frictionally driven by the vibration element, an outer peripheral portion, and a connecting portion connecting between the main body and the outer peripheral portion, and wherein the main body has a degree of freedom thereof with respect to the bearing member restricted in other directions than a direction of rotation thereof and a thrust direction of the shaft member, and flexural rigidity of the connecting portion in a direction parallel to the rotational axis is lower than flexural rigidity of the main body and the outer peripheral portion.

### Advantageous Effects of Invention

According to the invention, the driven element that receives a frictional driving force from the vibration element is configured to have a structure in which the outer peripheral portion and the main body are formed integrally via the connecting portion which is low in flexural rigidity. With this configuration, even when the outer peripheral portion receives an external force, the connecting portion is deformed to prevent the external force from affecting rotation of the main body, whereby it is possible to cause the vibration actuator to have a stable rotational driving performance.

Further features of the present invention will become apparent from the following description of exemplary embodiments (with reference to the attached drawings).

### BRIEF DESCRIPTION OF DRAWINGS

FIG. 1 is a perspective view of the appearance of a vibration actuator according to a first embodiment of the invention.

FIG. 2A is a top view of the vibration actuator shown in FIG. 1.

FIG. 2B is a cross-sectional view of the vibration actuator, taken on line A-A of FIG. 2A.

FIG. 3A is an exploded perspective view showing the structure of a junction between a driven element body and a gear as components of the vibration actuator.

FIG. 3B is a cross-sectional view showing the structure of the junction between the driven element body and the gear.

FIG. 4A is a schematic perspective view useful in explaining the function of the gear as a component of the vibration actuator.

FIG. 4B is a schematic cross-sectional view useful in explaining the function of the gear.

FIG. 5 is a view useful in explaining the relationship between a force that the gear as the component of the vibration actuator receives through meshing with an external gear, and fitting portions of the gear and a bearing member.

FIG. 6 is a schematic cross-sectional view of a driven element body and a gear as components of a vibration actuator according to a second embodiment of the invention.

FIG. 7 is a schematic cross-sectional view of a driven element body and a gear as components of a vibration actuator according to a third embodiment of the invention.

FIG. 8 is a schematic cross-sectional view of a driven element body and a gear as components of a vibration actuator according to a fourth embodiment of the invention.

FIG. 9 is a schematic perspective view of a digital camera in which the vibration actuator shown in FIG. 1 is mounted.

### DESCRIPTION OF EMBODIMENTS

The present invention will now be described in detail below with reference to the accompanying drawings showing embodiments thereof.

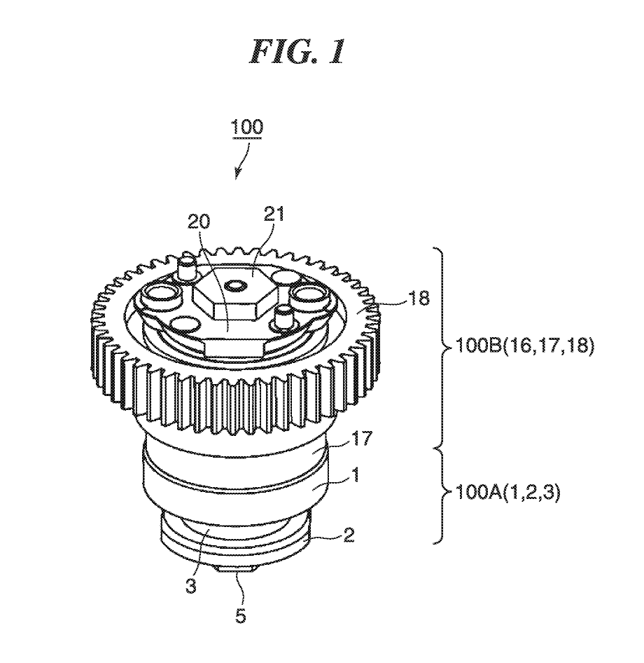

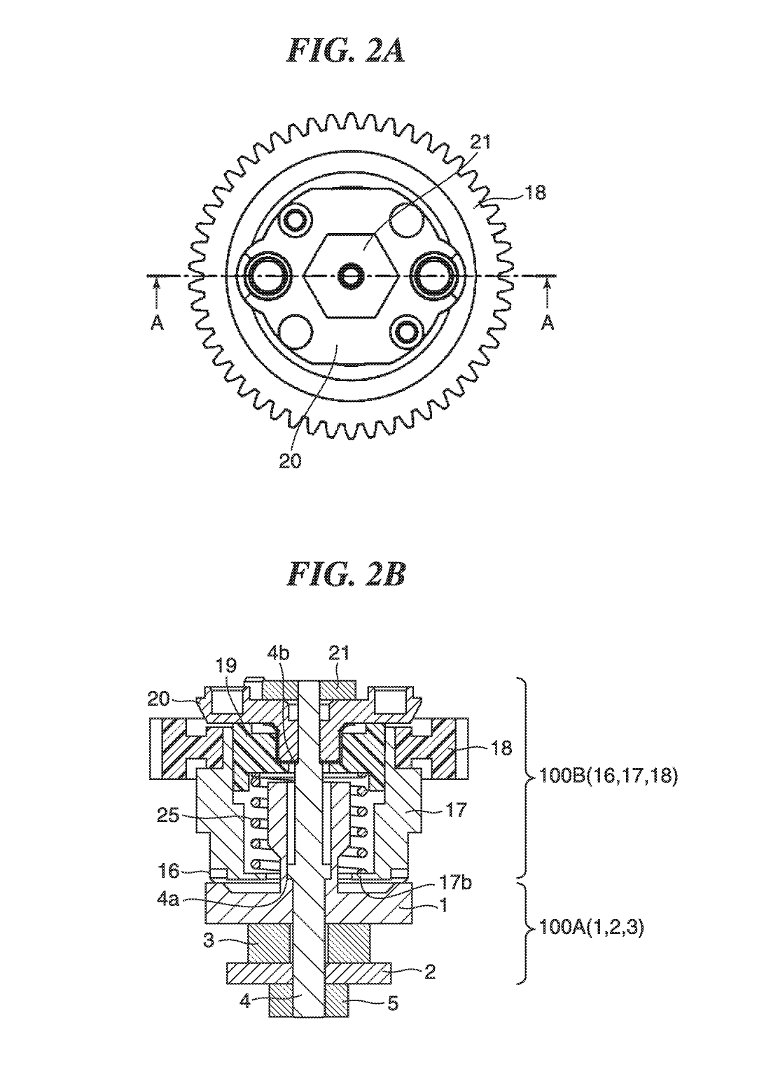

FIG. 1 is a perspective view of the appearance of a vibration actuator 100 according to a first embodiment of the invention. FIG. 2A is a top view of the vibration actuator 100, and FIG. 2B is a cross-sectional view taken on line A-A of FIG. 2A.

The vibration actuator 100 is comprised of a vibration element 100A, a driven element 100B, a shaft (shaft member) 4, a nut 5, a bearing member 19, a flange 20, a nut 21, and a pressure spring 25. The vibration element 100A is comprised of a first elastic body 1, a second elastic body 2, and a piezoelectric element 3. The driven element 100B is comprised of a contact spring member 16, a driven element body 17, and a gear 18. According to the present embodiment, the vibration actuator 100 is configured such that the driven element 100B rotatably supported on the shaft 4 is driven by vibrations excited in the vibration element 100A held on the shaft 4, for rotation about the shaft 4 as a rotational axis.

Note that the bearing member 19 and the pressure spring 25 rotate about the shaft 4 as the rotational axis in unison with the driven element 100B, as described hereinafter. However, in the present embodiment, as described hereinabove, the contact spring member 16, the driven element body 17, and the gear 18, which rotate by receiving a frictional driving force from the vibration element 100A to transmit the rotational driving force (rotational output) to the outside, form the driven element 100B. Further, in the following description, a side of the vibration actuator 100 closer to the nut 5 is referred to as a lower side, and a side of the vibration actuator 100 closer to the nut 21 is referred to as an upper side, for convenience of explanation.

The first elastic body 1, the second elastic body 2, and the piezoelectric element 3, which form the vibration element 100A and each have an annular shape, are fixed to respective predetermined locations in a thrust direction (vertical direction) of the shaft 4, by a flange portion 4a formed on the shaft 4 and the nut 5. The piezoelectric element 3 as an electromechanical energy conversion element has a structure in which a plurality of piezoelectric ceramics are layered one upon another with electrodes therebetween, and, for example, each electrode of one layer has two independent semicircular electrodes. Note that a flexible printed circuit board (not shown) for feeding electric power to the piezoelectric element 3 is disposed between the piezoelectric element 3 and the second elastic body 2.

The contact spring member 16 having an annular shape is joined e.g. by an adhesive to the outer periphery of a lower end (end toward the first elastic body 1) of the driven element body 17 having an annular shape, and an end of the contact spring member 16 with which the first elastic body 1 is brought into contact has a shape designed to have an appropriate spring property. Note that a portion of the first elastic body (upper surface of the first elastic body 1) which is brought into contact with the contact spring member 16 has been subjected to abrasion resistance treatment (quenching treatment, nitriding treatment, or the like e.g. in a case where the first elastic body 1 is formed of a stainless material). Similarly, the contact spring member 16 has been subjected to abrasion resistance treatment.

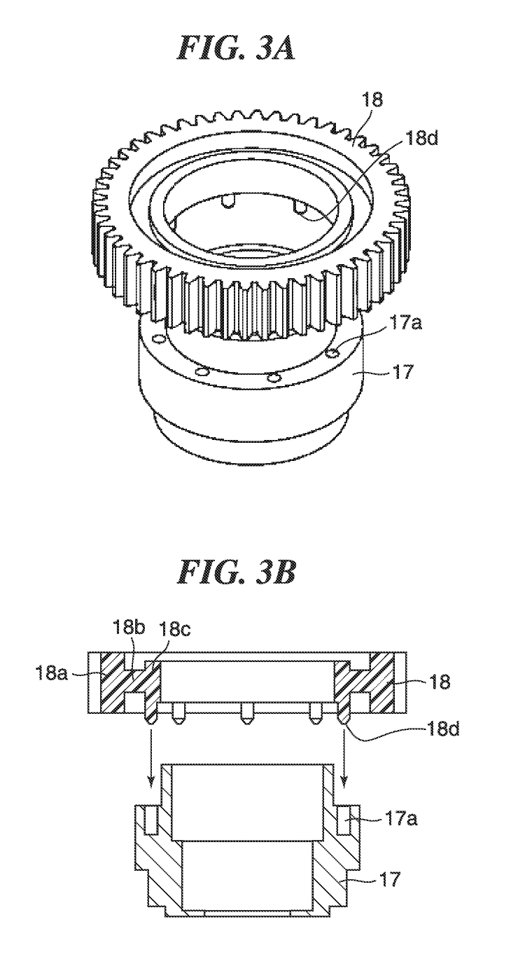

The gear 18 having an annular shape serves as an output transmitting member for transmitting a rotational driving force of the driven element body 17 to the outside. The gear 18 is joined to an upper end (opposite end from the end where the contact spring member 16 is joined) of the driven element body 17, as described in detail hereinafter with reference to FIGS. 3A and 3B. Note that a principle of how the driven element body 17 and the gear 18 are rotated via the contact spring member 16 by vibrations excited in the vibration element 100A will be described hereinafter.

The bearing member 19 having an annular shape is disposed on an upper inner periphery of the driven element body 17, with the shaft 4 extending therethrough. The bearing member 19 is a slide bearing, and the outer periphery of the bearing member 19 and the inner periphery of the driven element body 17 are joined by being diametrically fitted to each other so as to enable the driven element body 17 to perform stable rotation without causing rotational deflection. Further, the inner periphery of the bearing member 19 is diametrically fitted on a portion of the flange 20 in a state rotatable relative to the flange 20. Thus, the degree of freedom of the driven element body 17 is restricted in the other directions than the direction of rotation thereof and the thrust direction of the shaft 4.

The flange 20 is assembled in the vibration actuator 100 in a state abutting against a positioning step portion 4b formed on the shaft 4 and rigidly secured to an end of the shaft 4 with the nut 21. The flange 20 functions as a positioning member for positioning the bearing member 19 in the thrust direction of the shaft 4. More specifically, the flange 20 is positioned in the thrust direction of the shaft 4, whereby the bearing member 19 in contact with an end face of the flange 20 is also positioned in the thrust direction of the shaft 4.

The pressure spring 25 is a pressure applying member for pressing the driven element body 17 toward the vibration element 100A to thereby bring the contact spring member 16 joined to the driven element body 17 into pressure contact with the first elastic body 1 of the vibration element 100A. In the present embodiment, the pressure spring 25 is formed by a coil spring and is configured to be interposed between a flange portion 17b, which protrudes inward, of the driven element body 17 and the bearing member 19.

In the vibration actuator 100 constructed as above, it is possible to cause two bending vibrations orthogonal to the thrust direction of the shaft 4 to be excited in the vibration element 100A by applying AC voltages different in phase to the respective electrode groups of the piezoelectric element 3 from a power source, not shown, via the flexible printed circuit board, not shown. In doing this, it is possible to adjust the phases of the respective AC voltages to be applied, to thereby give a temporal phase difference of 90 degrees between the two bending vibrations, which causes the bending vibrations of the vibration element 100A to rotate about the shaft 4.

Thus, elliptic motions are generated in the upper surface of the first elastic body 1 in pressure contact with the contact spring member 16, and the contact spring member 16 in pressure contact with this surface is frictionally driven. This cause the driven element 100B (the contact spring member 16, the driven element body 17, and the gear 18) to rotate about the shaft 4 in unison with the bearing member 19 and the pressure spring 25. At this time, in the vibration actuator 100, a large rotational force (torque) is generated in the driven element body 17 by the frictional driving, and the torque is transmitted to the outside via the gear 18.

FIG. 3A is an exploded perspective view showing the structure of a junction between the driven element body 17 and the gear 18. FIG. 3B is a cross-sectional view showing the structure of the junction between the driven element body 17 and the gear 18, in a state in which the driven element body 17 and the gear 18 are disassembled.

The driven element body 17 has a plurality of recesses 17a formed in an upper surface thereof, and the gear 18 has a plurality of protrusions 18d formed thereon at locations opposed to the recesses 17a, respectively. The protrusions 18d and the recesses 17a are aligned with each other, and the protrusions 18d are pressed into the associated recesses 17a, whereby the driven element body 17 and the gear 18 are connected to each other without play. Note that in the present embodiment, a molded article of a resin material, such as polyacetal (POM), is suitably used for the gear 18.

The outer periphery of the gear 18 is formed as a toothed wheel portion 18a having a gear shape formed with gear teeth, and the inner periphery of the gear 18 is formed as a fixed portion 18c formed thicker in the thrust direction of the shaft 4. The gear 18 has a configuration in which the toothed wheel portion 18a and the fixed portion 18c are connected by a connecting portion 18b and these portions are seamlessly integrally formed. The toothed wheel portion 18a functions as an output portion for outputting the rotational driving force of the driven element 100B to the outside, and meshes with an external gear (an external gear 30 referred to hereinafter, or the like) to cause rotation of the same. The connecting portion 18b is formed to be thinner in the thrust direction of the shaft 4 than the toothed wheel portion 18a and the fixed portion 18c.

Note that since the fixed portion 18c is formed with the protrusions 18d, the fixed portion 18c is coupled to the driven element body 17. Therefore, in the present embodiment, as mentioned hereinbefore, the driven element 100B is formed by the contact spring member 16, the driven element body 17, and the gear 18, and further, a body portion of the driven element 100B is formed by the contact spring member 16, the driven element body 17, and the fixed portion 18c of the gear 18. Further, the toothed wheel portion 18a of the gear 18 is an output portion of the driven element 100B, and the connecting portion 18b of the gear 18 is a connecting portion connecting between the body portion and the output portion of the driven element 100B.

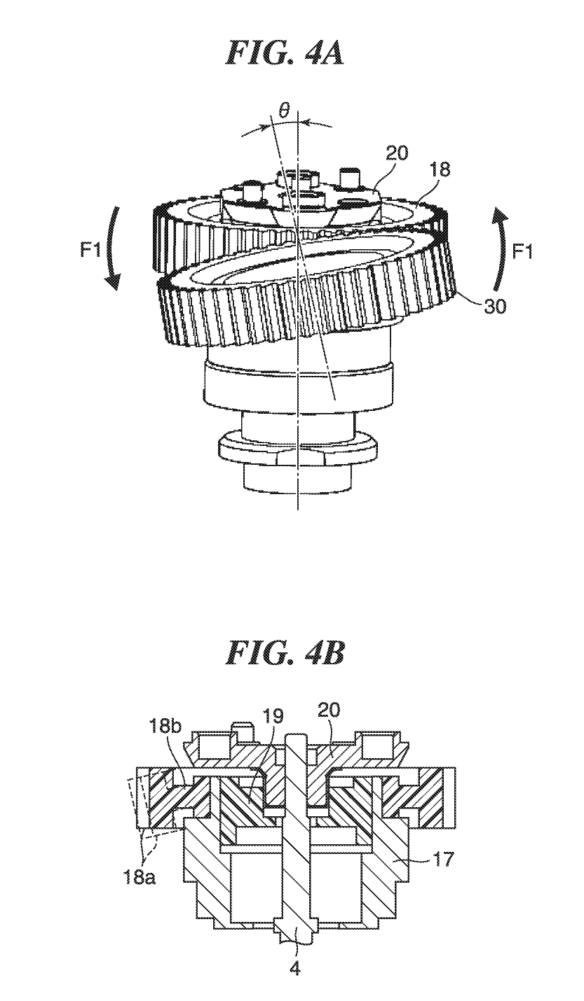

The gear 18 is configured as described above in order that in case the rotational axis of the external gear 30 in mesh with the gear 18 is inclined with respect to the rotational axis (shaft 4) of the gear 18, influence of such an inconvenience may be minimized. In the following, the function of the gear 18 will be described with reference to FIGS. 4A and 4B.

FIG. 4A is a schematic perspective view useful in explaining the function of the gear 18, and FIG. 4B is a schematic cross-sectional view useful in explaining the function of the gear 18. As shown in FIG. 4A, an inclination of θ degrees has occurred between the rotational axis of the external gear 30 and that of the gear 18. Such an inclination can be caused e.g. when the gear 18 and the external gear 30 are assembled or when an external force acts on the vibration actuator 100 or the external gear 30. In such a case, the gear 18 receives an external force F1 from the external gear 30. The external force F1 causes the driven element body 17 connected to the gear 18 to receive a moment of force that causes the same to be rotated to be inclined in the same direction as the external force F1 acts.

Here, diametrically-fitted portions of the driven element body 17 and the bearing member 19 and diametrically-fitted portions of the bearing member 19 and the flange 20 both have a function of restricting inclination of the gear 18 and the driven element body 17. However, in the diametrically-fitted portions of the bearing member 19 and the flange 20, there is a slight play (clearance) for enabling the bearing member 19 to rotate relative to the flange 20. For this reason, when the rigidity of the gear 18 in its entirety is high, there is a fear that the driven element body 17 is slightly inclined, which can cause degradation of the state of contact between the contact spring member 16 joined to the driven element body 17 and the vibration element 100A (the first elastic body 1), resulting in an unstable state of output, such as reduction of output, and generation of abnormal noise called chatter.

In view of this, the gear 18 has the connecting portion 18b formed between the toothed wheel portion 18a and the fixed portion 18c, and the connecting portion 18b is configured to have a relatively lower flexural rigidity in the thrust direction of the shaft 4 than the toothed wheel portion 18a and the fixed portion 18c. Even with this configuration, it is possible to secure necessary rigidity in the direction of rotation of the gear 18. Further, even when the external force F1 acts on the toothed wheel portion 18a, the connecting portion 18b is deformed as illustrated in FIG. 4B, whereby transmission of the external force F1 received by the toothed wheel portion 18a to the driven element body 17 can be suppressed. This makes it possible to prevent degradation of the state of contact between the contact spring member 16 and the vibration element 100A (the first elastic body 1), and therefore it is possible to avoid occurrence of the problems, such as reduction of output and generation of abnormal noise. Thus, in the vibration actuator 100, it is possible to prevent an external force acting on the output portion of the driven element 100B from adversely affecting the main body of the driven element 100B, so that it is possible to obtain a stable rotation driving performance.

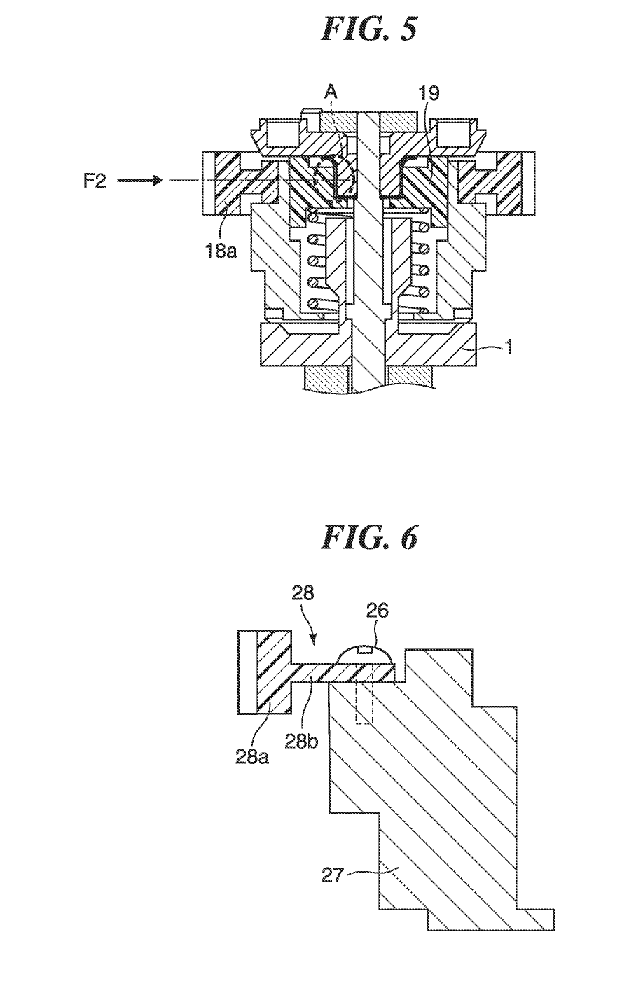

FIG. 5 is a view useful in explaining the relationship between a force that the gear 18 receives through meshing with the external gear 30, and fitting portions of the gear 18 and the bearing member 19. The shapes of teeth of the external gear 30 and the gear 18 are formed such that they have a predetermined pressure angle (e.g. 20°), and hence not only a rotational force in a tangent direction with respect to a path of rotation of the gear 18 but also a pressing force F2 in a radial direction acts on the gear 18. To prevent the pressing force F2 from acting as a moment that causes inclination of the driven element body 17, the vibration actuator 100 is configured such that an extension line of a force vector of the pressing force F2 substantially coincides with diametrically-fitted portions A of the bearing member 19 and the flange 20 (i.e. the pressing force F2 is received by the fitted portions of the bearing member 19 and the flange 20).

Note that it is desirable that the bearing member 19 is formed of a material excellent in slidability and also having a high vibration damping rate. Further, it is desirable that the vibration damping rate of the material forming the bearing member 19 is higher than that of a material forming the gear 18. This is because transmission of a vibration from the vibration element 100A can cause slight vibration of the driven element body 17, so that when the bearing member 19 is formed of a material having a low vibration damping rate (e.g. a metal material), there is a fear that chatter vibration or the like occurs, resulting in generation of abnormal noise. In view of this, a material of which a main ingredient is a fluorocarbon resin, such as polytetrafluoroethylene (PTFE), a polyacetal resin, a polyethylene resin, a polyamide resin, or the like, is suitably used for the bearing member 19.

As described above, in the present embodiment, the connecting portion having a smaller flexural rigidity in the direction parallel to the rotational axis than the main body and the output portion of the driven element 100B is provided in the driven element 100B, and an external force that the output portion receives in a direction orthogonal to the rotational axis is received by the fitting portions of the main body and the bearing. This makes it possible to stably drive the driven element 100B for rotation even when the external force acts on the output portion. Further, since the main body can be formed to have a high rigidity, it is possible to enhance responsiveness. Note that since the pressure applying member for bringing the driven element 100B into pressure contact with the vibration element 100A is disposed in a manner surrounding the rotating shaft, it is possible to make the driven element 100B difficult to be adversely affected by dimensional variations of component parts and the like.

FIG. 6 is a schematic cross-sectional view of a driven element body 27 and a gear 28 as components of a vibration actuator according to a second embodiment of the invention. The driven element body 27 and the gear 28 are members replacing the driven element body 17 and the gear 18 as components of the vibration actuator 100 according to the first embodiment. The other component members of the vibration actuator according to the second embodiment than the driven element body 27 and the gear 28 are the same as those of the vibration actuator 100, and therefore description thereof is omitted.

The outer periphery of the gear 28 is formed as a toothed wheel portion 28a having a gear shape formed with gear teeth, and the toothed wheel portion 28a functions as an output portion for outputting a rotational driving force of the driven element to the outside. In the gear 28, the inner periphery of the toothed wheel portion 28a is seamlessly formed integrally with a connecting portion 28b which has a flat annular shape (washer shape) and is formed to be thinner in the thrust direction of the shaft 4 than the toothed wheel portion 28a. The connecting portion 28b is fixed to the upper surface of the driven element body 27 with a plurality of screws 26, thereby connecting between the toothed wheel portion 28a and the driven element body 27 (body portion of the driven element).

Similar to the gear 18 of the vibration actuator 100 according to the first embodiment, the gear 28 has a high rigidity in the direction of rotation thereof, and the flexural rigidity of the connecting portion 28b in the thrust direction of the shaft 4 is lower than that of the toothed wheel portion 28a. With this, the vibration actuator according to the second embodiment can provide the same advantageous effects as provided by the vibration actuator 100 according to the first embodiment.

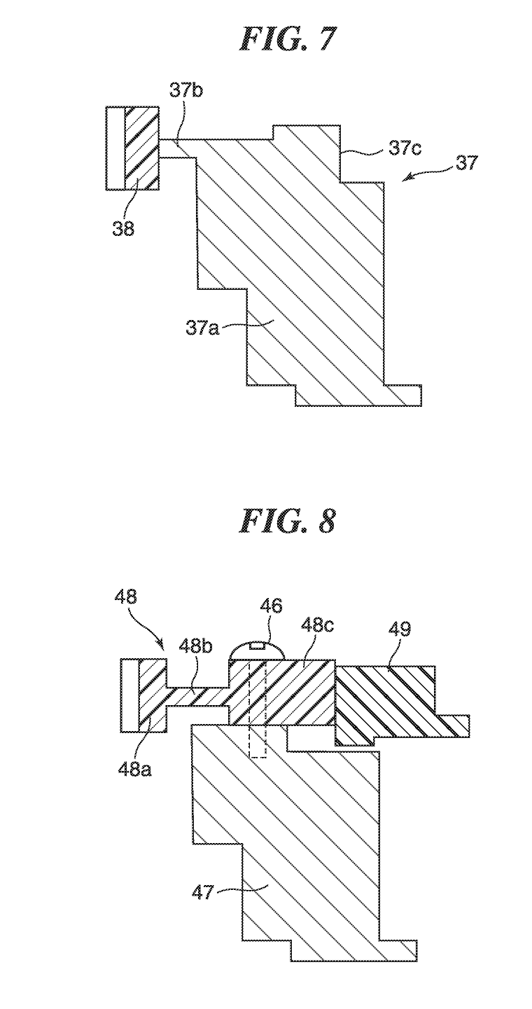

FIG. 7 is a schematic cross-sectional view of a driven element body 37 and a gear 38 as components of a vibration actuator according to a third embodiment of the invention. The driven element body 37 and the gear 38 are members replacing the driven element body 17 and the gear 18 as components of the vibration actuator 100 according to the first embodiment. Similar to the description of the second embodiment, description of the other component members of the vibration actuator than the driven element body 37 and the gear 38 will be omitted.

The driven element body 37 is a member formed by integrally forming the connecting portion 28b of the gear 28 and the driven element body 27 of the vibration actuator according to the second embodiment with each other. More specifically, the driven element body 37 is comprised of a main body portion 37a and a flange-shaped connecting portion 37b integrally protruding from the main body portion 37a in a radial direction. The gear 38 having an annular shape and functioning as an output portion of the driven element is disposed outside the connecting portion 37b, in a state joined to the connecting portion 37b. In the driven element body 37, the main body portion 37a and the connecting portion 37b are seamlessly integrally formed of the same material, such as a metal material. On the other hand, the gear 38 is a member corresponding to the toothed wheel portion 18a of the gear 18 of the vibration actuator 100 according to the first embodiment, and is formed of a resin material similarly to the gear 18. The gear 38 and the driven element body 37 are joined to each other by an adhesive or formed integrally by insert molding or the like. Note that the driven element body 37 and the bearing member 19 (not shown in FIG. 7) are diametrically fitted to each other at a stepped portion 37c formed in an upper portion of the inner periphery of the driven element body 37.

Similar to the gear 18 of the vibration actuator 100 according to the first embodiment, a structure of the gear 38 and the connecting portion 37b provided in the driven element body 37 has a high rigidity in the direction of rotation thereof. On the other hand, the connecting portion 37b is formed such that the flexural rigidity thereof in the thrust direction of the shaft 4 is lower than that of the gear 38. With this, the vibration actuator according to the third embodiment can provide the same advantageous effects as provided by the vibration actuator 100 according to the first embodiment.

FIG. 8 is a schematic cross-sectional view of a driven element body 47, a gear 48, and a bearing member 49 as components of a vibration actuator according to a fourth embodiment of the invention. The driven element body 47, the gear 48, and the bearing member 49 are members replacing the driven element body 17, the gear 18, and the bearing member 19 as components of the vibration actuator 100 according to the first embodiment. Similar to the description of the second embodiment, description of the other component members of the vibration actuator than the driven element body 47, the gear 48, and the bearing member 49 will be omitted.

The outer periphery of the gear 48 is formed as a toothed wheel portion 48a having a gear shape formed with gear teeth, and the inner periphery of the gear 48 is formed as a fixed portion 48c formed to be thicker in the thrust direction of the shaft 4. The gear 48 has a configuration in which the toothed wheel portion 48a and the fixed portion 48c are connected by a connecting portion 48b, and these portions are seamlessly integrally formed. The toothed wheel portion 48a functions as an output portion for outputting the rotational driving force of the driven element to the outside. The connecting portion 48b is formed to be thinner in the thrust direction of the shaft 4 than the toothed wheel portion 48a and the fixed portion 48c.

The gear 48 has the fixed portion 48c rigidly secured to the driven element body 47 e.g. with screws 46 or the like. At this time, the fixed portion 48c of the gear 48 is engaged with the bearing member 49 to thereby serve to guide the driven element including the driven element body 47. The present embodiment is distinguished from the first embodiment in which the driven element body 17 and the bearing member 19 are diametrically fitted to each other, in that the fixed portion 48c of the gear 48 and the bearing member 49 are diametrically fitted to each other.

Similar to the gear 18 of the vibration actuator 100 according to the first embodiment, the gear 48 has a high rigidity in the direction of rotation thereof, and the connecting portion 48b has a lower flexural rigidity in the thrust direction of the shaft 4 than the toothed wheel portion 48a and the fixed portion 48c. With this, the vibration actuator according to the fourth embodiment can also provide the same advantageous effects as provided by the vibration actuator 100 according to the first embodiment.

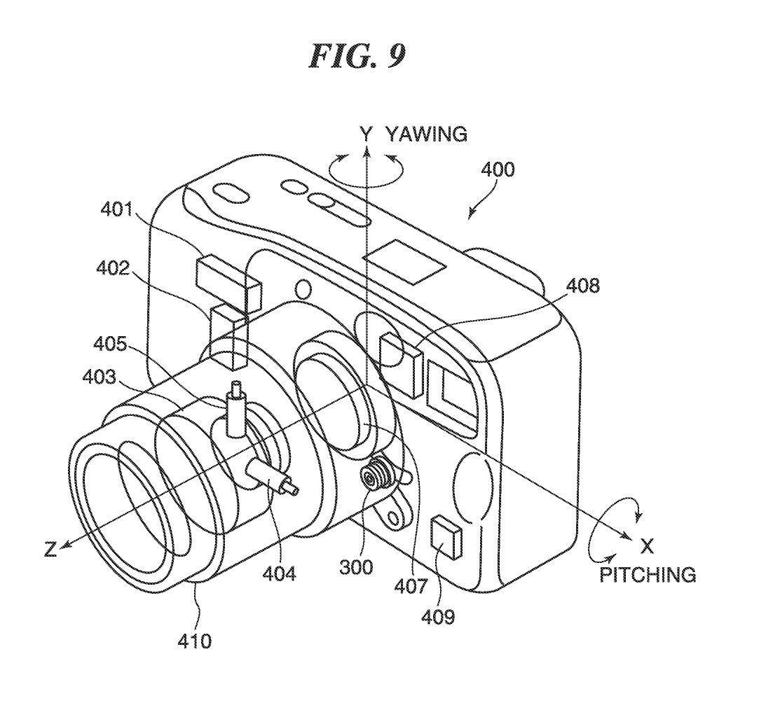

A fifth embodiment of the present invention is an example of application of the vibration actuator 100 described hereinabove to an image pickup apparatus which is an example of an electronic apparatus or a mechanical apparatus. FIG. 9 is a schematic perspective view of a digital camera 400 as an example of the image pickup apparatus, shown in a partially transparent state.

The digital camera 400 has a lens barrel 410 mounted on a front side thereof. The lens barrel 410 has disposed therein a plurality of lenses, not shown, including a focus lens 407, and a camera shake correction optical system 403. The camera shake correction optical system 403 is configured to be capable of performing vibration in a vertical direction (Y direction) and vibration in a left-right direction (X direction) by having rotations of biaxial coreless motors 404 and 405 transmitted thereto.

In a body of the digital camera 400, there are arranged a microcomputer (MPU) 409 which controls the overall operation of the digital camera 400, and an image pickup device 408. The image pickup device 408 is a photoelectric conversion device, such as a CMOS sensor or a CCD sensor, and converts an optical image formed by light passing through the lens barrel 410 to analog electric signals. The analog electric signals output from the image pickup device 408 are converted to digital signals by an analog-to-digital converter, not shown, and then are stored as image data (video data) in a storage medium, such as a semiconductor memory, not shown, after being subjected to predetermined image processing by an image processing circuit, not shown.

A gyro sensor 401 for detecting the amount of camera shake (vibration) in the vertical direction (pitching) and a gyro sensor 402 for detecting the amount of camera shake (vibration) in the horizontal direction (yawing) are disposed as internal devices within the body of the digital camera 400. The coreless motors 404 and 405 are driven in directions opposite to the directions of the vibrations detected by the respective gyro sensors 401 and 402, to vibrate the optical axis of the camera shake correction optical system 403. As a consequence, the vibration of the optical axis by camera shake is cancelled out, whereby it is possible to take an excellent photograph in which camera shake is corrected.

The vibration actuator 100 is used as a drive unit 300 for driving the focus lens 407 disposed in the lens barrel 410 in an optical axis direction (Z direction) via a gear train, not shown, to thereby position the same at an in-focus position. However, this is not limitative, but the vibration actuator 100 can be used for driving desired lenses, such as a zoom lens, not shown. Further, the vibration actuator 100 can be disposed in an interchangeable lens barrel removably attached to an image pickup apparatus body containing an image pickup device, as a drive unit for moving a focus lens or a zoom lens in an optical axis direction.

The vibration actuator 100 can be used for driving various members each requiring positioning, not only in the above-described image pickup apparatus but also in other electronic apparatuses and mechanical apparatuses. For example, the rotational driving force of the driven element can be used for driving a photosensitive drum or the like of an image forming apparatus, for rotation, for driving an arm of an articulated robot, for rotation, and for like other uses.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

For example, although in the vibration actuators according to the above-described embodiments, the vibration element is fixed and the driven element is driven for rotation, a configuration may be employed in which the driven element is fixed and the vibration element and the shaft 4 are rotated, to thereby take out the rotational driving force using the shaft 4 as the output portion. In this case, part or the whole of the outer periphery of the driven element is used as a fixed portion fixed to a frame or the like of an apparatus equipped with the vibration actuator, and in such a case, the outer periphery forming the fixed portion of the driven element is not required to have a toothed wheel shape. In a case where the shaft 4 as the output portion is inclined with respect to the fixed driven element e.g. when installation or by action of an external force or the like, the connecting portion of the driven element bends, whereby the state of contact between the driven element and the vibration element is held in good condition. This makes it possible to stably take out the rotational driving force to the outside.

Note that the arrangement for feeding electric power to the piezoelectric element 3 of the vibration element that rotates is not particularly limited. For example, by using an arrangement in which a metal plate for feeding electric power is fixed to the piezoelectric element 3 in a state electrically connected to a predetermined electrode of the piezoelectric element 3, and during rotation of the piezoelectric element 3 (vibration element) and the metal plate, the metal plate is constantly held in contact with a fixed power supply terminal, it is possible to feed electric power.

Further, although the bearing member 19 is described as a slide bearing, by way of example, this is not limitative, but it is possible to apply the present invention to any bearing member having a bearing function, such as a thrust ball bearing and a radial ball bearing. In this case, in order to prevent occurrence of abnormal noise caused e.g. by chatter vibration, it is desirable that a member formed of a resin or the like material having a high vibration damping rate is disposed between the fitting portions of the bearing member 19 and the driven element body 17.

### REFERENCE SIGNS LIST

1 first elastic body
2 second elastic body
3 piezoelectric element
4 shaft
5, 21 nut
16 contact spring member
17, 27, 37, 47 driven element body
18, 28, 38, 48 gear
18a, 48a toothed wheel portion
18b, 28b, 37b, 48b connecting portion
18c, 48c fixed portion
19, 49 bearing member
20 flange
25 pressure spring
100A vibration element
100B driven element cm 1. A vibration actuator, comprising:
   a vibration element having an elastic body and an electromechanical energy conversion element joined to said elastic body;
   a shaft member configured to hold said vibration element;
   a driven element in pressure contact with said elastic body, said driven element including a main body configured to be frictionally driven by said vibration element, an outer peripheral portion, and a connecting portion connecting between said main body and said outer peripheral portion;
   a bearing member joined to said driven element and rotatable with respect to said shaft member; and
   a pressure applying member disposed between said main body and said bearing member,
   wherein vibrations excited in said vibration element by application of a predetermined AC voltage to said electromechanical energy conversion element cause said vibration element and said driven element to rotate relative to each other about said shaft member as a rotational axis, and
   wherein said main body has a degree of freedom thereof with respect to said bearing member restricted in other directions than a direction of rotation thereof and a thrust direction of said shaft member, and flexural rigidity of said connecting portion in a direction parallel to the rotational axis is lower than flexural rigidity of said main body and said outer peripheral portion.

2. The vibration actuator according to claim 1, wherein said connecting portion has a smaller thickness in the thrust direction of said shaft member than said outer peripheral portion, and is formed into a flange shape.

3. The vibration actuator according to claim 1, wherein said outer peripheral portion is formed of a material different from said main body and said connecting portion.

4. The vibration actuator according to claim 3, wherein said outer peripheral portion is formed of a resin material, and said main body and said connecting portion are each formed of a metal material.

5. The vibration actuator according to claim 1, wherein said connecting portion and said outer peripheral portion are formed of the same material different from a material of said main body.

6. The vibration actuator according to claim 4, wherein said connecting portion and said outer peripheral portion are formed of a resin material, and said main body is formed of a metal material.

7. The vibration actuator according to claim 1, wherein said bearing member is formed of a material higher in vibration damping rate than a material forming said outer peripheral portion.

8. The vibration actuator according to claim 7, wherein said bearing member is formed of a material of which a main component is a resin.

9. The vibration actuator according to claim 1, wherein said bearing member is a slide bearing.

10. The vibration actuator according to claim 1, wherein said pressure applying member presses said main body against said vibration element, and
surrounds said bearing member.

11. The vibration actuator according to claim 1, further comprising a positioning member which is fixed to said bearing member, for positioning said bearing member in the thrust direction of said shaft member, and is diametrically fitted to said bearing member, and
wherein an external force acting on said outer peripheral portion in a radial direction of said shaft member is received by diametrically-fitted portions of said bearing member and said positioning member.

12. The vibration actuator according to claim 1, wherein said outer peripheral portion has a toothed wheel shape meshing with an external gear, and
wherein said vibration element and said shaft member are fixed, and said driven element is rotated, whereby a rotational driving force of said driven element is transmitted to said external gear.

13. The vibration actuator according to claim 1, wherein part or a whole of said outer peripheral portion is fixed, and said vibration element and said shaft member are rotated in unison, whereby a rotational driving force is applied from said shaft member.

14. An electronic apparatus including:
a vibration actuator configured to output a rotational driving force, and
a member configured to be moved by the rotational driving force output from said vibration actuator to a predetermined position to be positioned thereat,
wherein said vibration actuator comprises:
a vibration element having an elastic body and an electromechanical energy conversion element joined to said elastic body;
a shaft member configured to hold said vibration element;
a driven element in pressure contact with said elastic body, said driven element including a main body configured to be frictionally driven by said vibration element, an outer peripheral portion, and a connecting portion connecting between said main body and said outer peripheral portion;
a bearing member joined to said driven element and rotatable with respect to said shaft member; and
a pressure applying member disposed between said main body and said bearing member,
wherein vibrations excited in said vibration element by application of a predetermined AC voltage to said electromechanical energy conversion element cause said vibration element and said driven element to rotate relative to each other about said shaft member as a rotational axis, and
wherein said main body has a degree of freedom thereof with respect to said bearing member restricted in other directions than a direction of rotation thereof and a thrust direction of said shaft member, and flexural rigidity of said connecting portion in a direction parallel to the rotational axis is lower than flexural rigidity of said main body and said outer peripheral portion.

15. The vibration actuator according to claim 1, wherein said bearing member is disposed on an extension line of a force vector of a pressing force acting on said outer peripheral portion in a radial direction of said shaft member.
